(19) United States
(12) Patent Application Publication
(10) Pub. No.: US 2004/0127172 A1
(43) Pub. Date: Jul. 1, 2004

(54) Phase-error suppressor and a method of suppressing phase-error

(75) Inventors: Sander L. Gierkink, Hoboken, NJ (US); Salvatore Levantino, Milan (IT)

Correspondence Address: HITT GAINES P.C., P.O. BOX 832570, RICHARDSON, TX, 75083, US

(73) Assignee: Agere Systems Inc., Allentown, PA

(21) Appl. No.: 10/628,162

(22) Filed: Jul. 28, 2003

Related U.S. Application Data
(60) Provisional application No. 60/436,894, filed on Dec. 27, 2002.

(51) Int. Cl. H04B 1/02; H03C 3/00; H04L 27/20; H04L 7/00

(52) U.S. Cl. 455/91; 375/355; 332/103; 455/102

(57) ABSTRACT

The present invention provides a phase-error suppressor for use with a plurality of transistors having a common source coupled to a current generator that receives signals at a frequency. In one embodiment, the phase-error suppressor includes an inductor, coupled between the common source and the current generator, that resonates proportionally to the frequency with a first capacitance associated with the plurality of transistors. In one embodiment, the inductor resonates at about twice the frequency wherein input phase error is suppressed at output.

### CROSS-REFERENCE TO PROVISIONAL APPLICATION

This application claims the benefit of U.S. Provisional Application No. 60/436,894 entitled “High-Frequency Phase-Error Canceller” to Gierkink, et al., filed on Dec. 27, 2002, which is incorporated herein by reference.

### TECHNICAL FIELD OF THE INVENTION

The present invention is directed, in general, to radio frequency communications systems and, more specifically, to a phase-error suppressor associated with the image-rejecting down-converter, and a method of suppressing a phase-error of signals associated therewith.

### BACKGROUND OF THE INVENTION

Radio frequency (RF) signals are often down-converted to an intermediate frequency (IF) in a receiver by mixing the RF signals with signals from a local oscillator (LO) allowing further signal processing at a lower frequency. Though signal processing is simpler at a lower frequency, down-conversion to an IF typically creates an image problem. The image problem may be created by unwanted RF signals interleaved with the RF signals carrying information. Preventing an unwanted image is conventionally addressed by either pre-filtering the RF signal before mixing or by using an image-reject down-conversion scheme. An advantage of using the image-reject down-conversion scheme is that a full integration with a RF front-end of the receiver is available.

A typical implementation of an image-rejection down-converter is a Weaver architecture employing two mixers and a 90° phase shifter. One of the mixers down-converts a RF signal by mixing a cosine of a LO frequency signal and the other mixer down-converts the RF signal by mixing a sine of the LO frequency signal. The two resulting IF signals have a quadrature phase relation, or 90° phase shift, if both IF signals originated from a wanted received RF band and an opposite quadrature phase relation, or −90° phase shift, if both IF signals originated from an unwanted RF band. After delaying one of the resulting IF signals by 90° and summing the two resulting IF signals, an image band created by the unwanted RF signals may be rejected. Achieving acceptable image rejection, however, requires matching between the mixers, an accurate phase shift and an accurate LO quadrature.

In a conventional receiver, two separate Gilbert cells may be employed for the two mixers employing four phases of a LO reference at 0, 90, 180 and 270 degrees. The receiver may also employ LO buffers to provide isolation between a RF port and a LO port of the receiver. In order to provide immunity to common mode disturbances, the LO buffers may include two differential stages. Since this down-conversion scheme employs two separate paths for the LO sine and LO cosine signals, the receiver may have little capability to reject any phase error between the sine and cosine signals of the LO. The phase accuracy, therefore, between the sine and cosine signals may directly affect the phase accuracy of the down-converted IF signals and, in turn, the achievable image rejection.

To improve phase error rejection, a quadrature stage as detailed in U.S. Pat. No. 6,029,059 entitled “QUADRATURE MIXER METHOD AND APPARATUS” to Jorgen Bojer, which is incorporated herein by reference in its entirety, may be employed to process four LO signals in a same stage. This quadrature stage topology has been proposed in the design of quadrature mixers since the two mixers may share a same RF transconductor allowing the substantial elimination of one source of imbalance between the two mixers.

In this quadrature mixer, a differential stage may be employed to substantially cancel input phase errors. If the two inputs of the stage are sinusoids with imperfect 180° phase relation, the inputs can be decomposed into differential-mode and common-mode components. If the stage has infinite common-mode rejection, the differential-mode component may be transferred to the output. Therefore, even in the presence of a 0/180° phase error at the input, the output signals may have insignificant phase error. In practice, a finite output resistance of a tail current generator and load imbalances may limit the achievable rejection of common-mode signals and, in turn, the output phase accuracy.

The quadrature mixer, however, may not adequately provide phase-error correction in high-frequency operations due to source stray capacitances of switching transistors and a drain capacitance of a current generator shunting the high-frequency currents to ground. A common source of the quadrature stage may have a voltage oscillation at four times a frequency of a LO from a rectifying operation of the quadrature mixer's four transistors. Additionally, a guard stage of the quadrature mixer may also have a voltage oscillation at twice the LO frequency caused by an input phase error. Since the current generator may have a low impedance at twice the LO frequency due to parasitic capacitances, a bias current for the four transistors is not constant but may have a component at twice the LO frequency allowing current pulses corresponding to a quadrature LO signal to shift with respect to in-phase LO signal current pulses. The input phase-error, therefore, may not be canceled at the output. Thus, a second-order harmonic impedance of the common source may be necessary to provide a quadrature phase error cancellation.

Accordingly, what is needed in the art is an improved method and apparatus for correcting a phase-error associated with RF receivers especially operating at a high frequency.

### SUMMARY OF THE INVENTION

To address the above-discussed deficiencies of the prior art, the present invention provides a phase-error suppressor for use with a plurality of transistors having a common source coupled to a current generator and configured to receive signals at a frequency. In one embodiment, the phase-error suppressor includes an inductor, coupled between the common source and the current generator, configured to resonate proportionally to the frequency with a first capacitance associated with the plurality of transistors. The inductor, therefore, is configured to have an inductance that is in resonance with the first capacitance at a frequency proportional to the frequency of the received signals.

In another aspect, the present invention provides a method of suppressing a phase-error for use with a plurality of transistors having a common source coupled to a current generator and configured to receive signals at a frequency. The method of suppressing includes coupling an inductor in series between the common source and the current generator and causing the inductor to resonate proportionally at the frequency with a first capacitance associated with the plurality of transistors thereby suppressing a phase-error associated with the signals.

In yet another aspect, the present invention provides an image-rejecting down-converter for use with a radio frequency (RF) receiver. The image-rejecting down-converter includes a local oscillator (LO) configured to provide an in-phase signal and a quadrature-phase signal at a frequency, a quadrature mixer configured to combine the in-phase and the quadrature-phase signals with a RF signal and a quadrature oscillator buffer coupled between the LO and quadrature mixer. The quadrature oscillator buffer includes a plurality of transistors having a common source coupled to a current generator that receives the in-phase and the quadrature-phase signals from the LO at the frequency. The quadrature oscillator buffer also includes an inductor, coupled between the common source and the current generator, that resonates proportionally to the frequency with a first capacitance associated with the plurality of transistors to suppress phase-error between the in-phase and the quadrature-phase signals.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

For a more complete understanding of the present invention, reference is now made to the following descriptions taken in conjunction with the accompanying drawings, in which:

FIG. 1 illustrates a block diagram of an embodiment of an image-rejecting down-converter constructed in accordance with the principles of the present invention;

FIG. 2 illustrates a block diagram of an embodiment of a quadrature oscillator buffer constructed according to the principles of the present invention;

FIG. 3 illustrates a plot representing input signals when no phase error is applied according to the principles of the present invention;

FIG. 4 illustrates a plot representing input signals when a phase error is applied according to the principles of the present invention;

FIG. 5 illustrates a block diagram of another embodiment of a quadrature oscillator buffer constructed according to the principles of the present invention;

FIG. 6 illustrates a block diagram of an embodiment of a quadrature mixer constructed according to the principles of the present invention; and

FIG. 7 illustrates a flow diagram of an embodiment of a method of suppressing a phase-error between signals constructed according to the principles of the present invention.

### DETAILED DESCRIPTION

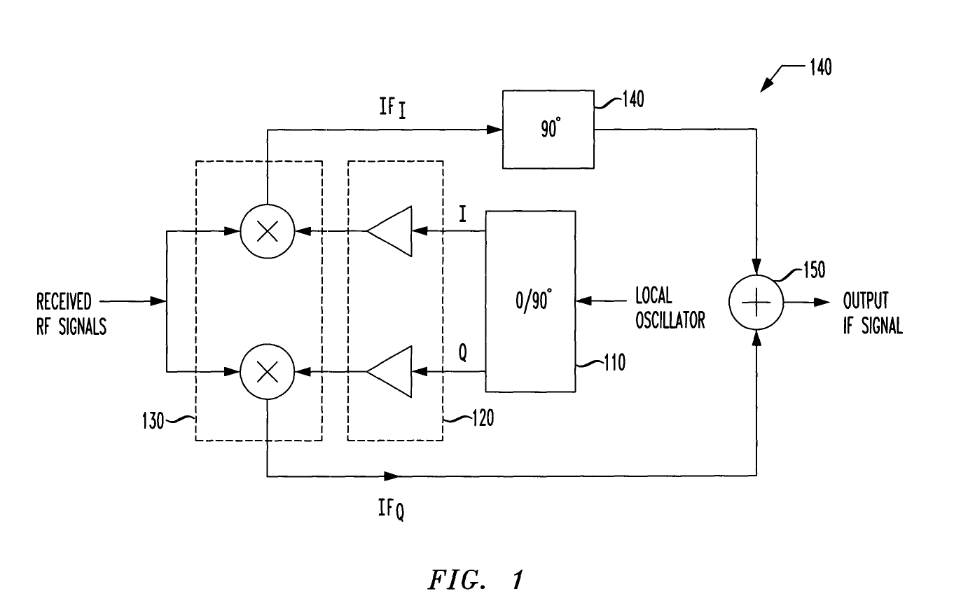

Referring initially to FIG. 1, illustrated is a block diagram of an image-rejecting down-converter, generally designated 100, constructed in accordance with the principles of the present invention. The image-rejecting down-converter 100 includes a local oscillator (LO) 110, a quadrature oscillator buffer 120, a quadrature mixer 130, a phase shifter 140 and an adder 150.

Typically, the image-rejecting down-converter 100 may be employed within a radio frequency (RF) receiver to down-convert a RF signal (denoted as a received RF signal) to an intermediate frequency (IF) for further signal processing. The image-rejecting down-converter 100 may employ a Weaver architecture. The RF receiver may be, for example, a mobile telephone, a personal digital assistant, a wireless laptop computer or another device configured to receive wireless data. The image-rejecting down-converter 100 may advantageously employ a phase-suppressor constructed in accordance to the principles of the present invention to provide image rejection. In some embodiments, either the quadrature oscillator buffer 120 or the quadrature mixer 130 may employ phase-error suppression as disclosed herein. In other embodiments, both the quadrature oscillator buffer 120 and the quadrature mixer 130 may employ phase-error suppression.

The LO 110, coupled to the quadrature oscillator buffer 120, may employ conventional oscillator components typically employed within an RF receiver. The LO 110 may be configured to provide an in-phase signal and a quadrature-phase signal at a designated frequency. In one embodiment, the designated frequency may be at least three GHz such as at five GHz. The in-phase and quadrature-phase signals may be sine and cosine signals at the designated frequency. Typically, the designated frequency of the LO 110 may proximate the frequency of the received RF signal. The in-phase and quadrature-phase signals, referred to as I and Q in FIG. 1, may be four periodic LO signals having about a 90 degree phase difference. For example, the in-phase and quadrature-phase signals may be four phases of a LO reference at about 0, 90, 180 and 270 degree phases, respectively. One skilled in the art will generally understand the construction and operation of a LO.

The quadrature oscillator buffer 120 may receive the in-phase and quadrature-phase signals from the LO 110. The quadrature oscillator buffer 120 may provide sufficient isolation between the received RF signal and the LO 110 to support combining the received RF signal and the in-phase and quadrature-phase signals. The quadrature oscillator buffer 120 may include a plurality of transistors having a common source coupled to a current generator and configured to receive the in-phase and the quadrature-phase signals from the LO 110 at the designated frequency. The plurality of transistors may be, for example, bipolar transistors or Metal Oxide Silicon Field Effect Transistors (MOSFETs). Accordingly, the common source may be a general term that also refers to a common emitter depending on the type of transistors employed. Additionally, the quadrature oscillator buffer 120 may include an inductor, coupled between the common source and the current generator, configured to resonate proportionally to the designated frequency with a first capacitance associated with the plurality of transistors to suppress phase-error between the in-phase and the quadrature-phase signals.

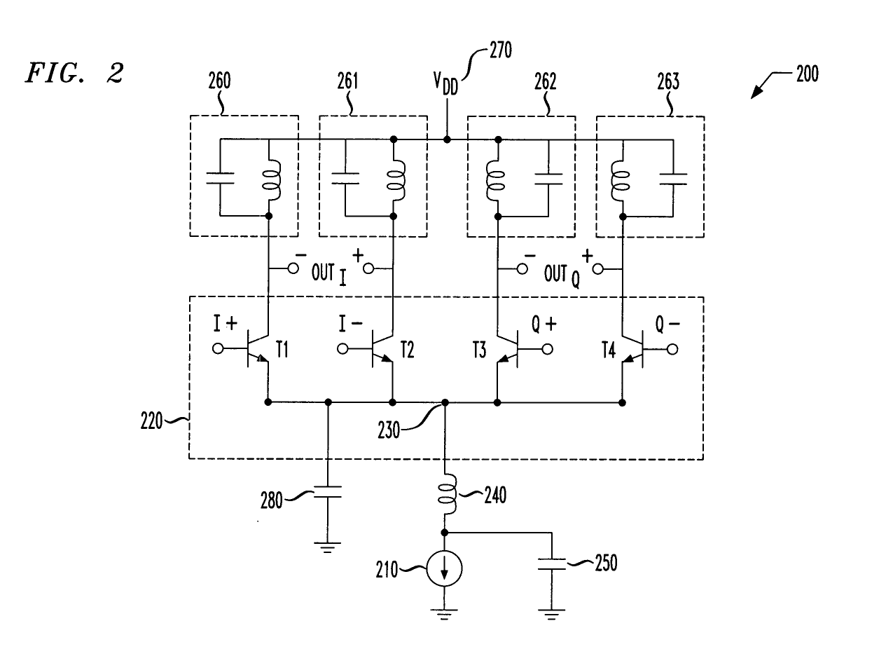

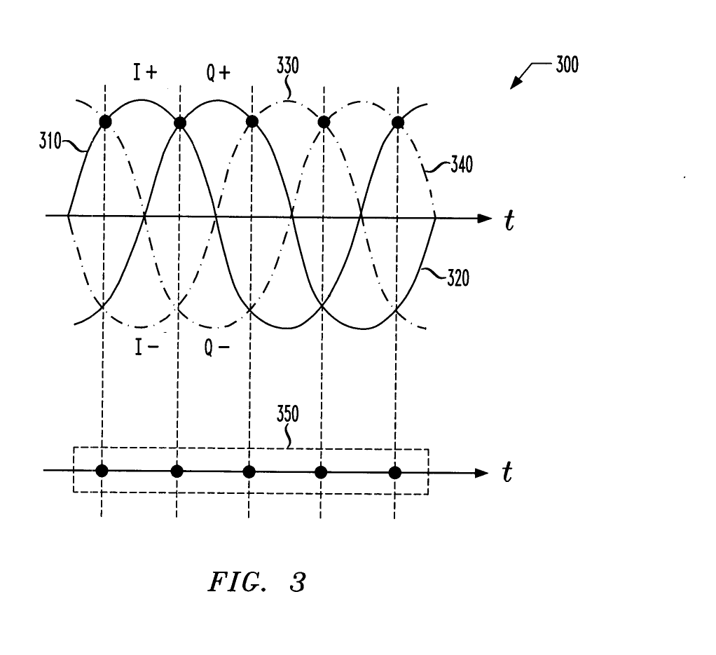

Typically, the first capacitance may be dominated by a gate-to-source capacitance or a base-to-emitter capacitance of the plurality of transistors. In a preferred embodiment, the inductor and the first capacitance may resonate at twice the designated frequency. Exemplary embodiments of the quadrature oscillator buffer 120 are discussed below with respect to FIGS. 2 and 3.

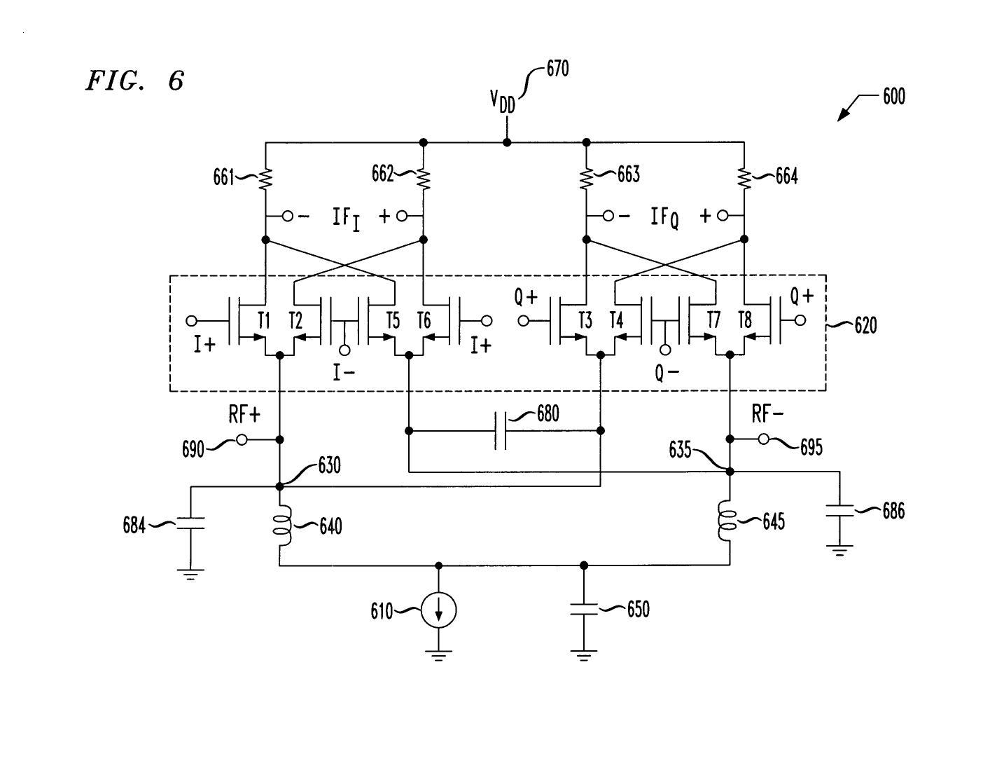

The quadrature mixer 130 may combine the received RF signal with the in-phase and quadrature-phase signals and provides a pair of IF signals, IF_{I} and IF_{Q}, having a quadrature relation. The quadrature mixer 130 may be a conventional mixer that employs two Gilbert cells. In a preferred embodiment, the quadrature mixer 130 may be a quadrature mixer as discussed below with respect to FIG. 6. As one skilled in the art will understand, a frequency of the IF signals IF_{I}, IF_{Q}, may be approximately a difference between a frequency of the received RF signal minus the designated frequency of the LO 110.

The phase shifter 140 may be a conventional phase shifter that delays the in-phase IF signal IF_{I} by 90 degrees. Of course, one skilled in the art will understand that in other embodiments, the phase shifter 140 may delay the quadrature-phase IF signal IF_{Q} by 90 degrees. Alternatively, other embodiments of the image-rejecting down-converter 100 may employ conventional filtering circuits for both the IF signals IF_{I}, IF_{Q}, instead of the phase shifter 140 to provide assistance in image rejecting or canceling.

The adder 150 may also include conventional components that sums the delayed IF signals IF_{I}, IF_{Q}, to provide an output IF. The in-phase IF signal IF_{I} and the quadrature-phase IF signal IF_{Q}, have a quadrature-phase relation, 90 degree phase shift, if originated from a wanted band of the received RF signal and an opposite quadrature-phase, −90 degree phase shift, if they originated from an unwanted band of the received RF signal. Typically, the output IF signal is then further processed to retrieve data from the wanted band of the received RF signal.

Turning now to FIG. 2, illustrated is a block diagram of an embodiment of a quadrature oscillator buffer, generally designated 200, constructed according to the principles of the present invention. The quadrature oscillator buffer 200 includes a bias current generator 210, a plurality of transistors 220, a common source 230, an inductor 240, a capacitor 250, resonant loads 260, 261, 262, 263 coupled to a power supply voltage 270 and a first capacitance 280. The quadrature oscillator buffer 200 provides a quadrature-phase output signal OUT_{Q} and an in-phase output signal OUT_{I}.

The bias current generator 210 may provide a bias current for the plurality of transistors 220. The bias current generator 210 may be coupled to the inductor 240 and parallel-coupled to the capacitor 250. The capacitor 250 may be configured to shunt the inductor 240 to ground at a selected RF. In some embodiments, the capacitor 250 may have a value at least ten times greater than a value of the first capacitance 280.

The bias current generator 210 may also be coupled to the plurality of transistors 220 at the common source 230. The plurality of transistors 220 are each separately coupled to the power supply voltage 270 via a respective one of the resonant loads 261, 262, 263, 264. The plurality of transistors 220 are configured to receive orthogonal in-phase and quadrature-phase components of a LO signal at about 0, 90, 180 and 270 degrees. Each of the in-phase and quadrature-phase components may be at a frequency of the LO. In FIG. 2, the in-phase components are represented by I and the quadrature-phase components are represented by Q. For example, I+ represents an in-phase component signal at about 0 degrees, I− represents an in-phase component signal at about 90 degrees, Q+ represents a quadrature-phase component signal at about 180 degrees and Q− represents a quadrature-phase component signal at about 270 degrees.

The inductor 240 may be configured to have an inductance in resonance with the first capacitance 280 at a frequency proportional to the frequency of the LO. The first capacitance 280 may be associated with the the plurality of transistors 220. Typically, the first capacitance 280 is dominated by a base-emitter capacitance of the plurality of transistors 220. In a preferred embodiment, the inductor 240 is designed to be at resonance with an emitter-ground stray capacitance of the plurality of transistors 220 at twice the frequency of the LO. At twice the LO frequency, an impedance of the bias current generator 210 may increase to a parallel loss resistance, represented by R=4πf_{LO}LQ_{L}, of the inductor 240 and the first capacitance 280, where f_{LO} is the LO frequency and L and Q_{L} are the inductance and the quality factor of the inductor 240, respectively. An amplitude of the sinusoids applied at I+, I−, Q+, Q−, may be several hundreds of a mV such that the bias current provided by the bias current generator 210 may only flow into one of the plurality of transistors 220 for one-fourth of a period of the LO.

An achievable rejection of a phase-error between the in-phase and quadrature-phase signals may be proportional to gₘR where gₘ is a transconductance of each one of the plurality of transistors 220 and R is a parallel loss resistance of the inductor 240 and the first capacitance 280.

For the purposes of an example, the quadrature oscillator buffer 200 may be integrated in a Silicon-Germanium (SiGe) BiCMOS technology and designed to operate at a LO frequency of about five GHz. The plurality of transistors 220 may be SiGe bipolar transistors with a peak frequency f_{T} of about 45 GHz. The inductor 240 may be integrated on-chip and may have an effective inductance of about 1 nH and selected for operating at about 10 Ghz. The bias current generator 210 may provide a bias current of about three mA that may permit each one of the plurality of transistors 220 to operate at about its peak frequency f_{T}. The capacitor 250 may be a 10 pF capacitor.

The resonant loads 261, 262, 263, 264, may be 2 nH coupled with 300 fF capacitors. In other embodiments, two differential inductors may be employed to replace the resonant loads 261, 262, 263, 264, to save space and provide a higher quality factor. The in-phase and quadrature-phase component signals I+, I−, Q+, Q− may have a DC bias of about 1.25 V and an amplitude of about 200 mV (from DC to peak). The output swing may be about 700 mV (from DC to peak). The power supply voltage 270 may be about 2.5 V.

After delaying the quadrature-phase output signal OUT_{Q} with respect to the in-phase output signal OUT_{I}, the resulting quadrature accuracy may be ascertained. Time delay may be used to delay the in-phase output signal OUT_{I} by T_{LO}/4, where T_{LO} is a period of LO signals. An image rejection may be calculated as S/D where S is a sum of the delayed in-phase signal output signal OUT_{I} and the quadrature-phase output signal OUT_{Q} and D is a difference.

The quadrature oscillator buffer 200 has been operated with an input phase error of two degrees (that is a time delay 1.11 ps at five GHz), which would correspond to an image rejection of 35 dB. The image rejection at the output is 58 dB. The quadrature oscillator buffer 200, therefore, may be able to suppress a phase-error and improve the image-rejection by 23 dB.

Turning now to FIG. 3 with continued reference to FIG. 2, illustrated is a plot representing input signals when no phase error is applied according to the principles of the present invention. The plot includes input signals I+, I−, Q+, Q− with perfect phase relationships of 0, 90, 180, 270 degrees. The input signals I+, I−, Q+, Q− are represented by curves 310, 330, 320, 340, respectively. When curve 310 driving the input signal I+ crosses curve 320 driving the input signal Q+, the bias current provided by the bias current generator 210 may be shared by the transistors T1 and T3 of the plurality of transistors 220 while transistors T2 and T4 of the plurality of transistors 220 are off. Every crossing between the input signals I+, I−, Q+, Q− may occur at a same input voltage value. A voltage at node 230, which is represented by curve 350, may follow the same input voltage value minus the base-emitter voltage. Thus, curve 350 may be practically a constant.

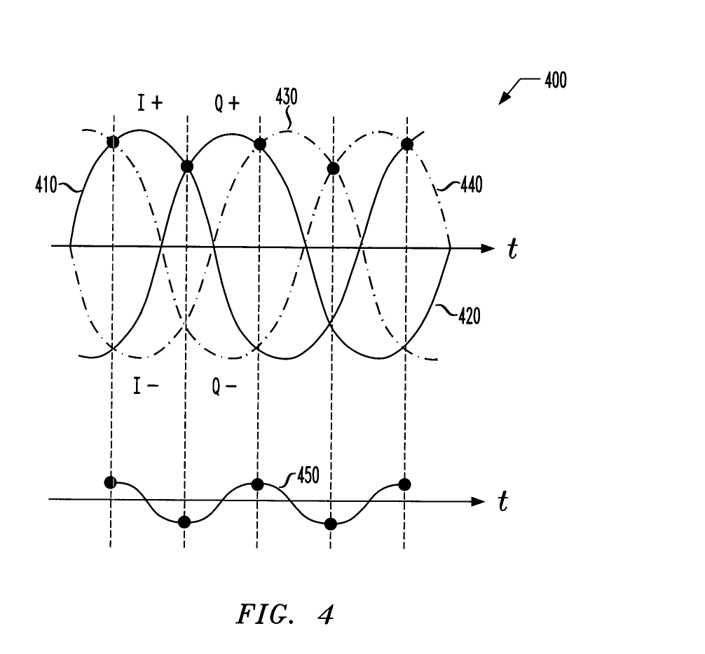

Turning now to FIG. 4 with continued reference to FIG. 2, illustrated is a plot representing input signals when a phase error is applied according to the principles of the present invention. The plot includes input signals I+, I−, Q+, Q− with some phase error between input signals I+ and I− and input signals Q+ and Q−. The input signals I+, I−, Q+, Q− are represented by curves 410, 430, 420, 440, respectively. In FIG. 4, crossings between curves 410, 430, 420, 440 may occur at different input voltage values. The voltage at node 230 which may be represented by curve 450, may be a sinusoid running at about twice the LO frequency. If the signal represent by the curve 450 is rejected, the input phase error may not be transferred to the output.

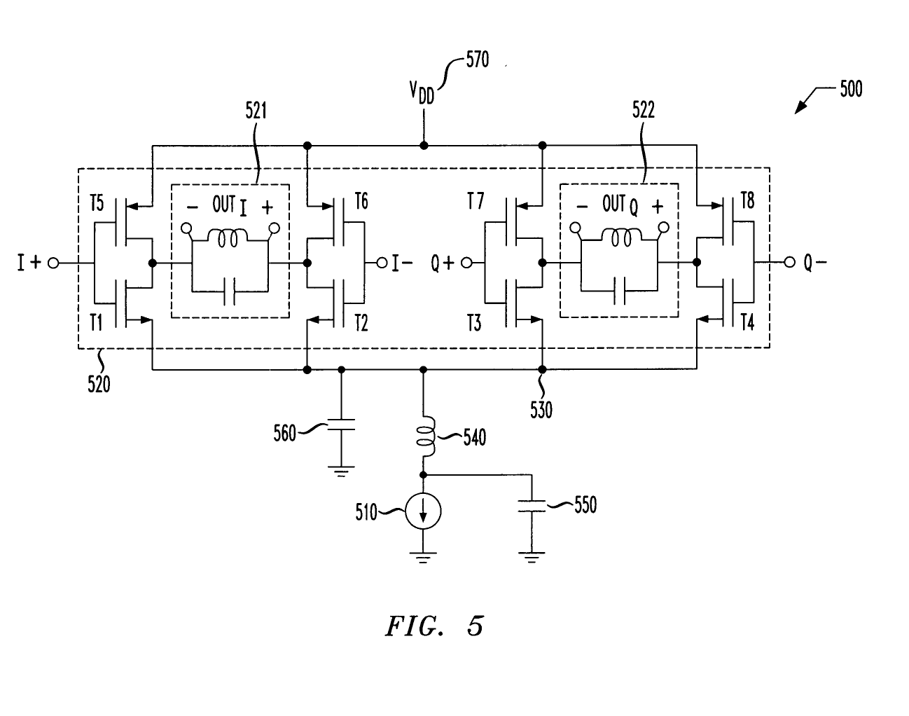

Turning now to FIG. 5, illustrated is a block diagram of another embodiment of a quadrature oscillator buffer, generally designated 500, constructed according to the principles of the present invention. The quadrature oscillator buffer 500 includes a bias current generator 510, a plurality of transistors 520, a first and second LC resonator 521, 522, associated with the plurality of transistors 520, a common source 530, an inductor 540, a capacitor 550, a first capacitance 560 and a voltage supply voltage 570. The plurality of transistors 520 includes a first set of n-type transistors T1-T4 and a second set of p-type transistors T5-T8.

Typically, the quadrature oscillator buffer 500 may be employed within a RF receiver and may suppress phase errors between in-phase and quadrature-phase signals received thereto (e.g., from a LO). The bias current generator 510 may be coupled to the inductor 540 and parallel-coupled to the capacitor 550. The capacitor 550 may be configured to shunt the inductor 540 to ground at a selected RF. The bias current generator 510 may provide a bias current for the plurality of transistors 520. The bias current generator 510 may be coupled through the inductor 540 to the transistors T1-T4 at the common source 530.

The first set of transistors T1-T4 and the second set of transistors T5-T8 may be configured to receive orthogonal in-phase and quadrature-phase component signals at 0 degrees (I+), 90 degrees (I−), 180 degrees (Q+) and 270 degrees (Q−) (I+, I−, representing in-phase component signals and Q+, Q−, representing quadrature-phase component signals). Each of the in-phase and quadrature-phase component signals may be at a frequency of the LO.

The inductor 540 may be configured to resonate proportionally to the frequency of the LO with the first capacitance 560. The first capacitance 560 may be associated with a gate-to-source capacitance of the transistors T1-T4. In a preferred embodiment, the inductor 540 may be designed to resonate at twice the frequency of the LO with the source-to-ground stray capacitance of the transistors T1-T4. The capacitor 550 may be designed to have a value at least ten times greater than a value of the first capacitance 560. At twice the LO frequency, the impedance of the bias current generator 510 may increase to a parallel loss resistance, represented by R=4πf_{LO}LQ_{L}, of the inductor 540 and the first capacitance 560, where f_{LO} is the LO frequency and L and Q_{L} are the inductance and the quality factor of the inductor 540, respectively.

The first and second LC resonators 521, 522, are coupled between ones of the plurality of transistors 520. The first and second LC resonators 521, 522, may be designed to resonate at the LO frequency to maximize a gain of the quadrature oscillator buffer 500.

Turning now to FIG. 6, illustrated is a block diagram of an embodiment of a quadrature mixer, generally designated 600, constructed according to the principles of the present invention. The quadrature mixer 600 includes a bias current generator 610, a plurality of transistors 620, a first common source 630, a second common source 635, a first inductor 640, a second inductor 645, a first capacitor 650, a plurality of loads 661, 662, 663, 664 (coupled to a power supply voltage 670), a second capacitor 680, a first capacitance 684, a second capacitance 686 and RF ports 690, 695.

The quadrature mixer 600 may be employed within a RF receiver to suppress phase error between in-phase and quadrature-phase signals of, for instance, a LO. In some embodiments, the quadrature mixer 600 may be coupled to a quadrature oscillator buffer, such as the quadrature oscillator buffers illustrated in FIGS. 2 and 5, that also provides phase error suppression. Thus, the quadrature mixer 600 may advantageously cooperate with a quadrature oscillator buffer to provide additional phase error suppression in the RF receiver.

The bias current generator 610 may be coupled to the first inductor 640 and the second inductor 645. Additionally, the bias current generator 610 may be parallel-coupled to the first capacitor 650. The first capacitor 650 may be configured to shunt the first inductor 640 and the second inductor 645 to ground at a selected RF. The bias current generator 610 may provide a bias current for the plurality of transistors 620 through the first common source 630 and the second common source 635.

The plurality of transistors 620 may be coupled to either the first common source 630 or the second common source 635 and to the power supply voltage 670 via the plurality of loads 661, 662, 663, 664. The plurality of transistors 620 may be configured to receive orthogonal in-phase and quadrature-phase component signals at about 0, 90, 180 and 270 degrees. Each of the in-phase and quadrature-phase component signals may be at a frequency of the LO.

The first inductor 640 and the second inductor 645 may be configured to resonate proportionally to the frequency of the LO with the first capacitance 684 and the second capacitance 686. The first and second capacitances 684, 686, may be associated with a capacitance of the plurality of transistors 620 coupled thereto. The capacitance may be dominated by a base-to-emitter capacitance of the plurality of transistors 620. In a preferred embodiment, the first inductor 640 and the second inductor 645 may be designed to resonate at twice the frequency of the LO with an emitter-to-ground stray capacitance of transistors T1-T4 and transistors T5-T8 of the plurality of transistors 620, respectively. The capacitor 650 may be designed to have a value at least ten times greater than a value of the first and second capacitances 684, 686. At twice the LO frequency, the impedance of the bias current generator 610 seen by the first common source 630 and the second common source 635 may increase to a parallel loss resistance, represented by R=4πf_{LO}LQ_{L}, of the first and second inductors 640, 645, and the first and second capacitances 684, 686, where f_{LO} is the LO frequency and L and Q_{L} are the inductance and the quality factor of the first and second inductors 640, 645, respectively.

The second capacitor 680 may be configured to resonate at a RF frequency with the first and second capacitances 684, 686, and the first and second inductors 640, 645. The RF ports 690, 695 may be configured to receive a RF signal, for example, from a RF transmitter. Typically, the RF signal includes data directed to the RF receiver. The RF signal may be at a frequency of about five GHz. The quadrature mixer 600 may down-convert the RF signal employing the in-phase and quadrature-phase signals received by the plurality of transistors 620.

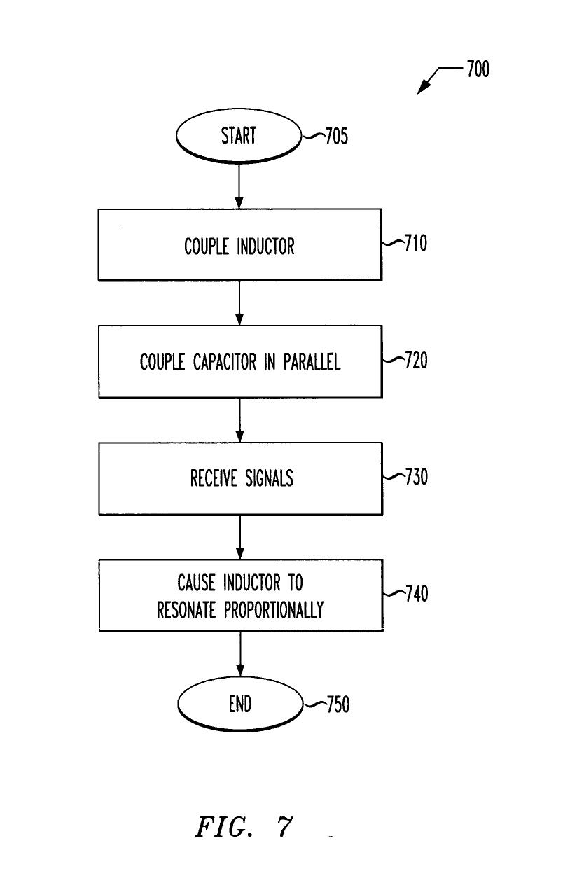

Turning now to FIG. 7, illustrated is a flow diagram of an embodiment of a method of suppressing a phase-error between signals, generally designated 700, constructed according to the principles of the present invention. The method starts in a step 705 with an intent to suppress the phase-error.

After starting, an inductor is coupled between a current generator and a common source of a plurality of transistors configured to receive signals at a frequency in a step 710. The signals may be quadrature related signals of a LO employed within a RF receiver. The plurality of transistors may be employed within a quadrature oscillator buffer, a quadrature oscillator or a quadrature mixer. The inductor may be sized based on the frequency of the signals and a capacitance of the plurality of transistors.

After coupling the inductor, a capacitor is parallel-coupled to the current generator in a step 720. The capacitor may also be coupled to the inductor. The capacitor may shunt the inductor to ground at a selected RF. The RF may be the frequency of a RF signal received by the quadrature mixer that may be combined with the quadrature related signals of the LO. The capacitor may be sized based on the inductor and the RF frequency.

After coupling the inductor, the signals are received at the frequency in a step 730. The frequency may be at least three GHz and, more specifically, may be five GHz. The signals may be four periodic LO signals having about a 90 degree phase difference. For example, the signals may be orthogonal in-phase and quadrature-phase component signals of a LO signal at about 0, 90, 180 and 270 degrees.

After receiving the signals, the inductor is caused to resonate proportionally to the frequency with a capacitance of the plurality of transistors in a step 740. The inductor may be advantageously selected to resonate based on the frequency and the capacitance of the plurality of transistors. The capacitance of the plurality of transistors may be dominated by a gate-to-source capacitance. In a preferred embodiment, the inductor may be caused to resonate at twice the frequency. After causing the inductor to resonate, the method of suppressing phase-error ends in a step 750.

While the methods disclosed herein have been described and shown with reference to particular steps performed in a particular order, it will be understood that these steps may be combined, subdivided or reordered to form an equivalent method without departing from the teachings of the present invention. Accordingly, unless specifically indicated herein, the order and/or the grouping of the steps are not limitations of the present invention. Also, while phase-error suppression has been described with respect to specific components, systems and subsystems, it should be understood that a phase-error suppressor as described herein may be employed with or in other systems and still be within the broad scope of the present invention. For information regarding RF communication theory in general, please refer to B. Razavi, RF Microelectronics, Prentice Hall PTR, 1997 which is incorporated herein by reference in its entirety as background material.

Although the present invention has been described in detail, those skilled in the art should understand that they can make various changes, substitutions and alterations herein without departing from the spirit and scope of the invention in its broadest form.

What is claimed is:

1. A phase-error suppressor for use with a plurality of transistors having a common source coupled to a current generator and configured to receive signals at a frequency, comprising:
an inductor, coupled between said common source and said current generator, configured to resonate proportionally to said frequency with a first capacitance associated with said plurality of transistors.

2. The phase-error suppressor as recited in claim 1 wherein said plurality of transistors and said current generator form a portion of a system selected from the group consisting of:
a quadrature oscillator buffer,
a quadrature oscillator, and
a quadrature mixer.

3. The phase-error suppressor as recited in claim 1 wherein said inductor and said first capacitance resonate at twice said frequency.

4. The phase-error suppressor as recited in claim 1 wherein said first capacitance is dominated by a base-to-emitter capacitance of at least one of said plurality of transistors.

5. The phase-error suppressor as recited in claim 1 further comprising a capacitor coupled to said inductor and coupled in parallel to said current generator, said capacitor being configured to shunt said inductor to ground at a selected radio frequency (RF).

6. The phase-error suppressor as recited in claim 1 wherein said frequency is at least three GHz.

7. The phase-error suppressor as recited in claim 1 where said signals are four periodic local oscillator signals having a 90 degree phase difference.

8. A method of suppressing a phase-error for use with a plurality of transistors having a common source coupled to a current generator and configured to receive signals at a frequency, comprising:
coupling an inductor in series between said common source and said current generator; and
causing said inductor to resonate proportionally at said frequency with a first capacitance associated with said plurality of transistors thereby suppressing a phase-error associated with said signals.

9. The method as recited in claim 8 wherein said plurality of transistors and said current generator form a portion of a system selected from the group consisting of:
a quadrature oscillator buffer,
a quadrature oscillator, and
a quadrature mixer.

10. The method as recited in claim 8 wherein said inductor and said first capacitance resonate at twice said frequency.

11. The method as recited in claim 8 wherein said first capacitance is dominated by a gate-to-source capacitance of said transistors.

12. The method as recited in claim 8 further comprising coupling a capacitor to said inductor and in parallel to said current generator, said capacitor shunting said inductor to ground at a selected radio frequency (RF).

13. The method as recited in claim 8 wherein said frequency is at least three GHz.

14. The method as recited in claim 1 wherein said signals are four periodic local oscillator signals having a 90 degree phase difference.

15. An image-rejecting down-converter for use with a radio frequency (RF) receiver, comprising:
a local oscillator (LO) configured to provide an in-phase signal and a quadrature-phase signal at a frequency;
a quadrature mixer configured to combine said in-phase and said quadrature-phase signals with a RF signal; and
a quadrature oscillator buffer, coupled between said LO and said quadrature mixer, including:
a plurality of transistors having a common source coupled to a current generator and configured to receive one of said in-phase and said quadrature-phase signals from said LO at said frequency; and
an inductor, coupled between said common source and said current generator configured to resonate proportionally to said frequency with a first capacitance associated with said plurality of transistors to suppress a phase-error between said in-phase and said quadrature-phase signals.

16. The image rejecting down-converter as recited in claim 15 wherein said quadrature mixer, includes:
a second plurality of transistors having a second common source coupled to a second current generator and configured to receive one of said in-phase and said quadrature-phase signals at said frequency; and
a second inductor, coupled between said second common source and said second current generator, configured to resonate proportionally to said frequency with a second capacitance associated with said second plurality of transistors to suppress phase-error between said in-phase and said quadrature-phase signals.

17. The image rejecting down-converter as recited in claim 15 wherein said inductor and said first capacitance resonate at twice said frequency.

18. The image rejecting down-converter as recited in claim 15 wherein said first capacitance is dominated by a base-to-emitter capacitance of at least one of said plurality of transistors.

19. The image rejecting down-converter as recited in claim 15 wherein said quadrature oscillator buffer further comprises a capacitor, coupled to said inductor and coupled in parallel to said current generator, said capacitor being configured to shunt said inductor to ground at a selected RF.

20. The image rejecting down-converter as recited in claim 15 wherein said frequency is at least three GHz.

21. The image rejecting down-converter as recited in claim 15 where said in-phase and said quadrature-phase signals are four periodic local oscillator signals having a 90 degree phase difference.
